(19) United States
(12) Patent Application Publication
(10) Pub. No.: US 2018/0088187 A1
(43) Pub. Date: Mar. 29, 2018

(54) MAGNETIC SENSOR AND MAGNETIC SENSOR SYSTEM

(71) Applicant: AISIN SEIKI KABUSHIKI KAISHA, Kariya-shi (JP)

(72) Inventor: Katsuaki TAKAHASHI, Yokohama-shi (JP)

(73) Assignee: AISIN SEIKI KABUSHIKI KAISHA, Kariya-shi (JP)

(21) Appl. No.: 15/704,663

(22) Filed: Sep. 14, 2017

(30) Foreign Application Priority Data
Sep. 29, 2016 (JP) 2016-191210

(51) Int. Cl. G01R 33/07; G01R 33/00

(52) U.S. Cl. CPC G01R 33/07; G01R 33/0029

(57) ABSTRACT

A magnetic sensor includes: a first Hall element that measures magnetic flux density; a second Hall element that measures the magnetic flux density; and a base member where the first Hall element is mounted on one surface, and the second Hall element is mounted on the other surface, in which the first Hall element and the second Hall element are disposed such that a measurement surface of the first Hall element and a measurement surface of the second Hall element are parallel to each other, and are symmetrical to the base member.

### CROSS REFERENCE TO RELATED APPLICATIONS

This application is based on and claims priority under 35 U.S.C. §119 to Japanese Patent Application 2016-191210, filed on Sep. 29, 2016, the entire contents of which are incorporated herein by reference.

### TECHNICAL FIELD

This disclosure relates to a magnetic sensor that measures magnetic flux density by using a Hall element, and a magnetic sensor system.

### BACKGROUND DISCUSSION

In the related art, a magnetic sensor using a Hall element has been used for various use purposes. For example, there is a case where the magnetic sensor is used in order to measure a rotation angle of a rotating object. Specifically, a permanent magnet is included in the rotating object, a change of magnetic flux (magnetic flux density depending on the magnetic flux) which is generated from the permanent magnet is detected, and the rotation angle of the rotating object is calculated based on a measurement result. Here, it is known that mobility is changed if stress is applied to a semiconductor (for example, silicon) configuring the Hall element. Since the change of the mobility has an influence (causes an error) on an output (for example, an electric current or a voltage) of the Hall element, it is not possible to accurately measure the magnetic flux density. As a result, it is not possible to calculate the rotation angle with accuracy. Therefore, in a case where the measurement of the rotation angle is performed by using the Hall element, a technology for preventing such an output change of the Hall element has been studied (for example, JP 2013-140133A (Reference 1), JP 2014-41093A (Reference 2), JP 2008-292182A (Reference 3), JP 2015-15390A (Reference 4), and JP 9-45974A (Reference 5)).

A magnetic Hall sensor disclosed in Reference 1 is configured to include a sensor Hall element, and a stress measuring Hall element that measures mechanical stress which acts upon the sensor Hall element, to control a driving electric current or a driving voltage for driving the sensor Hall element based on the mechanical stress measured by the stress measuring Hall element, and to correct an output change of the sensor Hall element based on the mechanical stress.

A magnetic Hall sensor disclosed in Reference 2 is configured to include a magnetic measuring sensor Hall element, and a stress measuring sensor Hall element that measures mechanical stress which acts upon the sensor Hall element, to control a driving electric current or a driving voltage for driving the sensor Hall element based on the mechanical stress measured by the stress measuring sensor Hall element, and to correct an output change of the sensor Hall element based on the mechanical stress by digital signal processing.

A Hall sensor disclosed in Reference 3 is configured to include a Hall element that is disposed on an insulating substrate, and a plastic resin that covers the Hall element and has a gap between the plastic resin and the Hall element, and to relieve stress which acts upon the Hall element with the plastic resin.

A Hall sensor disclosed in Reference 4 is configured to include two negative terminals in a pair of positive and negative voltage terminals which a Hall element has, to further include a variable resistor between the two negative terminals, and to correct an offset voltage of the Hall element by adjusting the variable resistor.

In a Hall IC disclosed in Reference 5, four Hall sensors are formed to be close to each other on a silicon substrate having (111) plane, and are disposed such that each Hall sensor is tilted by 45 degrees with respect to <110> direction. Thereby, the changes in piezoresistance coefficient due to stress become the same, a sum of the offset voltages of the respective Hall sensors is canceled out, and the influence of the stress is reduced.

Here, as a method for measuring the rotation angle by using the Hall element, for example, there are a magnetic field strength measurement type, and a magnetic field angle measurement type. The magnetic field strength measurement type measures the angle from a Hall voltage that is proportional to the strength of a vertical direction ingredient of the magnetic flux entering the Hall element. Since such a magnetic field strength measurement type greatly depends on temperature characteristic which the Hall element has in order to handle scalar quantity, the measurement accuracy of the angle may deteriorate at the time of high temperature or low temperature. Moreover, there is a problem that it is not possible to perform the angle measurement over a wide range because a linear region of the angle and the magnetic flux density is narrow.

On the other hand, in the magnetic field angle measurement type, two Hall elements are disposed so that the respective measurement directions are orthogonal to each other, and a vector operation is performed onto the Hall voltage of each Hall element, thereby, the measurement of the angle is performed. Since the scalar quantity is not directly used for the angle calculation by the vector operation, it is possible to make the influence of temperature dependence of the Hall element small. Since the linear region of the angle and the magnetic flux density becomes wide, it is possible to perform the angle measurement over the wide range.

As an error which is included in the measurement result in such a magnetic field angle measurement type, an offset error, a sensitivity error, and a phase error are exemplified. The offset error is an error that is caused by offset generated in the measurement result of the Hall element. The sensitivity error is an error that is caused by an electric factor included in the result in which the mobility of silicon is changed by the stress, and the phase error is an error that is caused by a mechanical factor included in the measurement result due to distortion of the disposition of two Hall elements.

In the technology disclosed in Reference 1, there is a need to separately dispose an element that measures an angle error generated by a piezo effect due to the stress, and it becomes a cause of a cost increase. The technology disclosed in Reference 1 can be applied to the magnetic field strength measurement type, but is not easily applied to the phase error of the magnetic field angle measurement type.

The technology disclosed in Reference 2 is not easily applied to the phase error of the magnetic field angle measurement type, in the same manner as the technology disclosed in Reference 1. In the technology disclosed in Reference 3, since peeling, steam destruction or the like is concerned in a situation where use environments are high temperature and high humidity, the use purpose may be limited.

The technology disclosed in Reference 4 and the technology disclosed in Reference 5 are not easily applied to the phase error of the magnetic field angle measurement type, in the same manner as the technology disclosed in Reference 1, and there is a possibility of cost increase in accordance with the increase of the number of components in particular.

Thus, a need exists for a magnetic sensor and a magnetic sensor system which are not susceptible to the drawback mentioned above.

### SUMMARY

A feature of a magnetic sensor according to an aspect of this disclosure resides in that the magnetic sensor includes a first Hall element that measures magnetic flux density, a second Hall element that measures the magnetic flux density, and a base member where the first Hall element is mounted on one surface, and the second Hall element is mounted on the other surface, in which the first Hall element and the second Hall element are disposed such that a measurement surface of the first Hall element and a measurement surface of the second Hall element are parallel to each other, and are symmetrical to the base member.

A feature of a magnetic sensor system according to another aspect of this disclosure resides in that the magnetic sensor system includes the magnetic sensor in which the first Hall element and the second Hall element are connected to each other in parallel, and an outside signal processing portion that calculates an average of an output of the first Hall element and an output of the second Hall element.

A feature of a magnetic sensor system according to still another aspect of this disclosure resides in that the magnetic sensor system includes the magnetic sensor, an outside storage portion that stores a difference between an output of the first Hall element and an output of the second Hall element per angle, and an outside signal processing portion that makes a correction by addition or subtraction of the difference stored in the outside storage portion to or from the output of the first Hall element or the output of the second Hall element.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a diagram illustrating a measurement principle of a magnetic sensor of a magnetic field angle measurement type;

FIG. 2 is a diagram illustrating a relationship between a measurement result and a magnetic field angle in each Hall element;

FIG. 3 is a diagram illustrating an example of an offset error;

FIG. 4 is a diagram illustrating an example of a sensitivity error;

FIG. 5 is a diagram illustrating an example of a phase error;

FIG. 6 is a perspective view of the magnetic sensor;

FIG. 7 is a side sectional view of the magnetic sensor;

FIG. 8 is a diagram illustrating stress which is generated in the Hall element in a case where a load is applied to the magnetic sensor; and

FIG. 9 is a diagram for describing reduction of the phase error by the magnetic sensor.

### DETAILED DESCRIPTION

### 1. Magnetic Sensor

A magnetic sensor according to an embodiment disclosed here is configured as a magnetic field angle measurement type, and is configured to be capable of reducing a phase error. Hereinafter, a magnetic sensor 1 of the embodiment will be described.

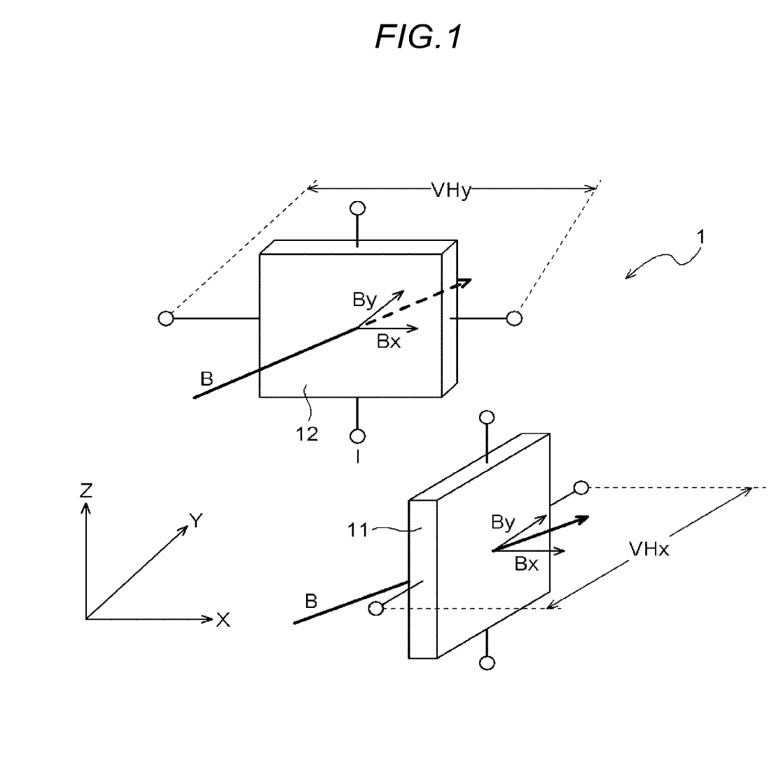

Here, a measurement principle of the magnetic field angle measurement type is illustrated in FIG. 1. As illustrated in FIG. 1, in the magnetic field angle measurement type, two Hall elements are disposed so as to be orthogonal to each other. Here, the Hall element that outputs a Hall voltage which is proportional to strength of an X-axis direction ingredient in a three-dimensional coordinate system of magnetic flux entering the magnetic sensor 1 is referred to as an X-direction Hall element 11, and the Hall element that outputs a Hall voltage which is proportional to the strength of a Y-axis direction ingredient in the three-dimensional coordinate system of the magnetic flux entering the magnetic sensor 1 is referred to as a Y-direction Hall element 12. In the magnetic field angle measurement type, an angle of the magnetic flux entering the magnetic sensor 1 is measured by performing vector operation onto each Hall voltage of the X-direction Hall element 11 and the Y-direction Hall element 12.

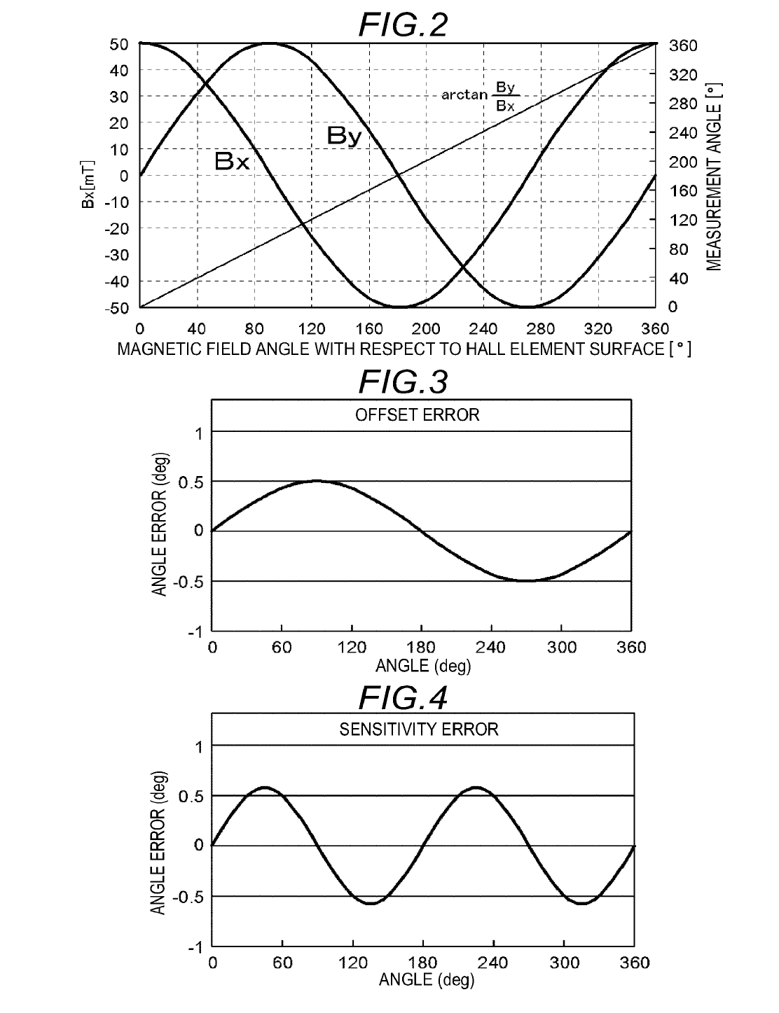

Specifically, the angle of the magnetic flux entering the Hall element is calculated by using a relationship between a measurement result and a magnetic field angle in each Hall element illustrated in FIG. 2. In FIG. 2, a vertical axis is density (magnetic flux density) of the magnetic flux entering each Hall element, and a horizontal axis is an incidence angle of the magnetic flux with respect to a measurement surface of the Hall element. Based on the output (Hall voltage) of the X-direction Hall element 11 and FIG. 2, the incidence angle with respect to the measurement surface of the X-direction Hall element 11 is calculated, and based on the output (Hall voltage) of the Y-direction Hall element 12 and FIG. 2, the incidence angle with respect to the measurement surface of the Y-direction Hall element 12 is calculated. From the measurement results, arctan (By/Bx) is calculated, and the angle of the magnetic flux is calculated.

Here, as a factor of an error which is included in the measurement result in the magnetic sensor of the magnetic field angle measurement type, an offset error, a sensitivity error, and a phase error are exemplified. If the offset error is referred to as Xoff and Yoff, the sensitivity error is referred to as SR, and the phase error is referred to as αx and αy, the error which is included in the measurement result of the magnetic sensor 1 is represented by the following expression (1). However, A is a true value.

$$Error = θ - arctan ( \frac{Yoff + sin ( θ - α y )}{Xoff + SR \times cos ( θ - α x )} ) \qquad ( 1 )$$

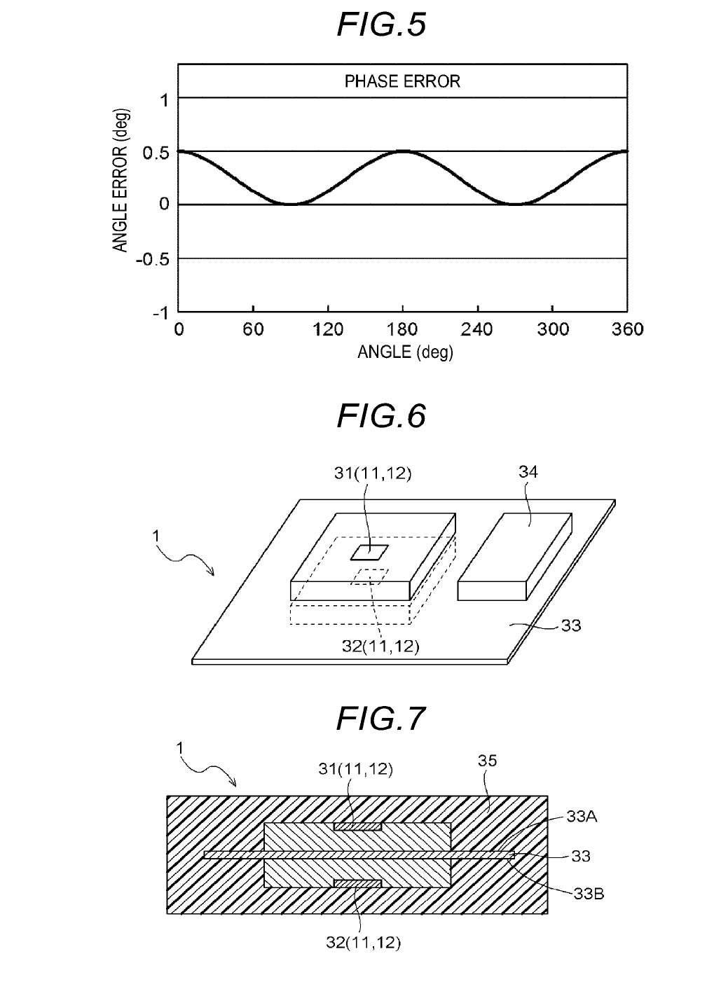

Angle errors due to the respective error factors are as illustrated in FIG. 3 to FIG. 5. FIG. 3 to FIG. 5 respectively illustrate the offset error, the sensitivity error, and the phase error, and the vertical axes thereof represent the angle error, and the horizontal axes thereof represent the angle. As illustrated in FIG. 3 to FIG. 5, the offset error and the sensitivity error are generated in a positive direction and a negative direction with respect to the angle error which is 0 (deg), but the phase error can have only the angle error which is a value of the positive direction. The magnetic sensor 1 according to the embodiment disclosed here is configured to be capable of correcting the phase error in particular.

FIG. 6 is a perspective view of the magnetic sensor 1 according to the embodiment disclosed here. As illustrated in FIG. 6, a first Hall element 31, a second Hall element 32, a base member 33, and a signal processing portion 34 are provided.

The first Hall element 31 measures the magnetic flux density. The magnetic flux density denotes a quantity of the magnetic flux passing through unit area. The magnetic flux is a sum of vertical direction ingredients of a magnetic flux line passing through a predetermined area in the magnetic field. Specifically, the magnetic flux density denotes the quantity of the magnetic flux per unit area entering the measurement surface of the first Hall element 31 which is included in the magnetic sensor 1 disposed in the magnetic field. Accordingly, the first Hall element 31 measures the quantity of the magnetic flux per unit area entering the measurement surface of the first Hall element 31 which is included in the magnetic sensor 1 disposed in the magnetic field. The first Hall element 31 is configured to include the X-direction Hall element 11 and the Y-direction Hall element 12 described above.

The second Hall element 32 also measures the magnetic flux density. The second Hall element 32, and the first Hall element 31 are included in the magnetic sensor 1. Therefore, the magnetic flux which is the same as the magnetic flux entering the first Hall element 31, enters the second Hall element 32. The second Hall element 32 measures the quantity of the magnetic flux per unit area entering the measurement surface of the second Hall element 32 which is included in the magnetic sensor 1 disposed in the magnetic field. The second Hall element 32 is configured to include the X-direction Hall element 11 and the Y-direction Hall element 12 described above.

In the base member 33, the first Hall element 31 is mounted on one surface 33A, and the second Hall element 32 is mounted on the other surface 33B. In the embodiment, a lead frame is used as a base member 33. Here, in the embodiment, the first Hall element 31 and the second Hall element 32 are formed on a silicon wafer, and are made into chips by dicing. In this manner, the first Hall element 31 which is made into a chip is mounted on one surface 33A of the lead frame, and the second Hall element 32 which is made into a chip is mounted on the other surface 33B of the lead frame.

At this time, the first Hall element 31 and the second Hall element 32 are disposed such that the measurement surface of the first Hall element 31 and the measurement surface of the second Hall element 32 are parallel to each other, and are symmetrical to the base member 33. As described above, the first Hall element 31 includes the X-direction Hall element 11 and the Y-direction Hall element 12, and the second Hall element 32 includes the X-direction Hall element 11 and the Y-direction Hall element 12. Therefore, the measurement surface of the first Hall element 31 is equivalent to the measurement surface of the X-direction Hall element 11 and the measurement surface of the Y-direction Hall element 12 which are included in the first Hall element 31, and the measurement surface of the second Hall element 32 is equivalent to the measurement surface of the X-direction Hall element 11 and the measurement surface of the Y-direction Hall element 12 which are included in the second Hall element 32. A phrase of “disposed to be parallel to each other, and to be symmetrical to the base member 33” denotes a case where two measurement surfaces to be symmetrical are oriented in the directions contrary to each other, and are disposed to be symmetrical by making the base member 33 as a boundary.

Accordingly, the measurement surface of the X-direction Hall element 11 included in the first Hall element 31 and the measurement surface of the X-direction Hall element 11 included in the second Hall element 32 are oriented in the directions contrary to each other, and are disposed in the target by making the base member 33 as a boundary, and the measurement surface of the Y-direction Hall element 12 included in the first Hall element 31 and the measurement surface of the Y-direction Hall element 12 included in the second Hall element 32 are oriented in the directions contrary to each other, and are disposed in the target by making the base member 33 as a boundary.

The first Hall element 31 and the second Hall element 32 are connected to each other in parallel. That is, in the embodiment, the X-direction Hall element 11 included in the first Hall element 31 and the X-direction Hall element 11 included in the second Hall element 32 are connected to each other in parallel, and the Y-direction Hall element 12 included in the first Hall element 31 and the Y-direction Hall element 12 included in the second Hall element 32 are connected to each other in parallel.

The signal processing portion 34 calculates an average of the output of the first Hall element 31 and the output of the second Hall element 32. In the embodiment, the first Hall element 31 and the second Hall element 32 output a voltage signal which is formed of the Hall voltage as an output. Therefore, in the embodiment, the signal processing portion 34 calculates the average of the Hall voltage of the X-direction Hall element 11 included in the first Hall element 31 and the Hall voltage of the X-direction Hall element 11 included in the second Hall element 32, and calculates the average of the Hall voltage of the Y-direction Hall element 12 included in the first Hall element 31 and the Hall voltage of the Y-direction Hall element 12 included in the second Hall element 32. Since it is possible to perform the calculation of such an average by known arithmetic processing, the description thereof will be omitted.

By configuring the magnetic sensor 1 in this manner, it is possible to reverse the phases of the stress applied to the first Hall element 31 and the second Hall element 32 to each other. FIG. 7 is a side sectional view of the first Hall element 31 and the second Hall element 32 in the magnetic sensor 1. In the example of FIG. 7, the first Hall element 31, the second Hall element 32, and the base member 33 are sealed with a resin 35.

As illustrated in FIG. 7, in a case where a load is not applied to the magnetic sensor 1, since the first Hall element 31 and the second Hall element 32 perform the outputs such that the phases are reversed to each other, the average calculated from two outputs is made as the output of the magnetic sensor 1, thereby, it is possible to reduce the phase error.

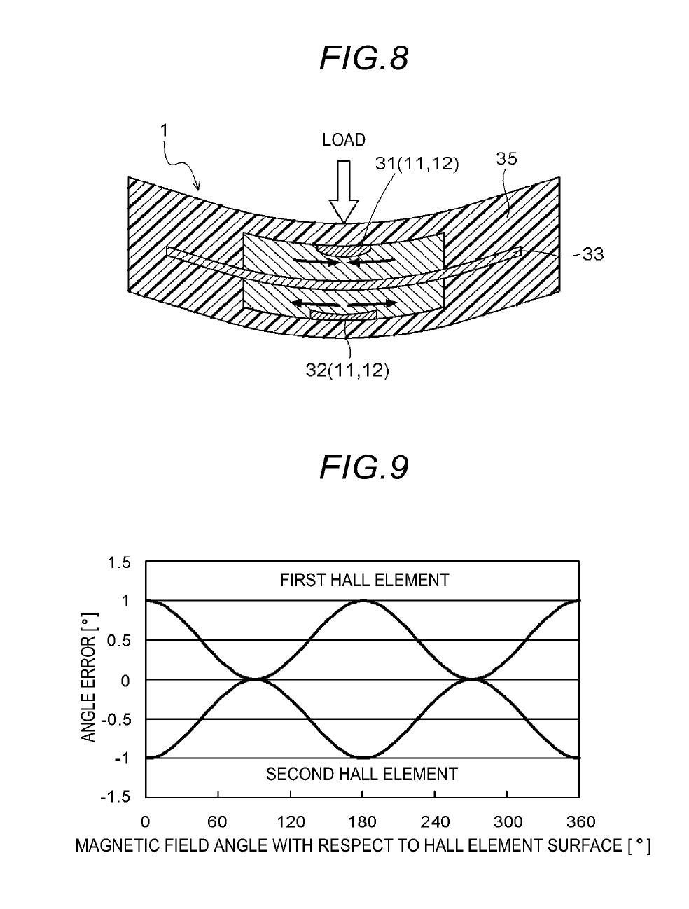

On the other hand, as illustrated in FIG. 8, in a case where the load is applied to the magnetic sensor 1, the load becomes a compression load in the first Hall element 31, and the load becomes a tensile load in the second Hall element 32. As illustrated in FIG. 9, since the loads have the same sizes, and the phases thereof are reversed to each other, it is possible to obtain the Hall voltage on which an influence of the stress is cancelled by calculating the average of the Hall voltages in the signal processing portion 34.

2. Other embodiments of Magnetic Sensor

In the embodiment described above, a case where the lead frame is used in the base member 33 is described, but it is possible to make a configuration in which a printed board is used.

In the embodiment described above, a case where the first Hall element 31 and the second Hall element 32 respectively have the X-direction Hall element 11 and the Y-direction Hall element 12 is described, but may be configured to include only one Hall element of the X-direction Hall element 11 and the Y-direction Hall element 12.

In the embodiment described above, a case where the magnetic sensor 1 includes the signal processing portion 34 is described, but the signal processing portion 34 may be separately disposed, without being included in the magnetic sensor 1.

In the embodiment described above, a case where the signal processing portion 34 calculates the average of the output of the first Hall element 31 and the output of the second Hall element 32 is described, but the magnetic sensor 1 may be configured to include a storage portion that stores a difference between the output of the first Hall element 31 and the output of the second Hall element 32 per angle, and a signal processing portion 34 that makes a correction by addition or subtraction of the difference stored in the storage portion to or from the output of the first Hall element 31 or the output of the second Hall element 32.

According to such a configuration, the difference between the output of the X-direction Hall element 11 of the first Hall element 31 and the output of the X-direction Hall element 11 of the second Hall element 32 per angle, and the difference between the output of the Y-direction Hall element 12 of the first Hall element 31 and the output of the Y-direction Hall element 12 of the second Hall element 32 per angle are stored in the storage portion, and the signal processing portion 34 may make the correction of the angle error of the output of the first Hall element 31 and the output of the second Hall element 32 by adding or subtracting the difference between the output of the first Hall element 31 and the output of the second Hall element 32 with respect to one thereof. According to the configuration, since the signal processing portion 34 does not perform division, with respect to a case where the correction is made by “the calculation of the average of the output of the first Hall element 31 and the output of the second Hall element 32” according to the embodiment described above, it is possible to reduce the calculation load.

### 3. Magnetic Sensor System

Next, a magnetic sensor system according to the embodiment disclosed here will be described. The magnetic sensor 1 includes the signal processing portion 34 therein, but the magnetic sensor system is different at a point that the signal processing portion is externally attached to the magnetic sensor system. Since other configurations are the same as those of the embodiment described above, hereinafter, the different point will be mainly described.

The magnetic sensor system of the embodiment is configured to include the magnetic sensor 1, and an outside signal processing portion. In the same manner as the embodiment described above, the magnetic sensor 1 includes the first Hall element 31, and the second Hall element 32, and the first Hall element 31 and the second Hall element 32 are connected to each other in parallel. The outside signal processing portion is a portion in which a functional portion of the signal processing portion 34 is externally attached with respect to the magnetic sensor 1, and calculates the average of the output of the first Hall element 31 and the output of the second Hall element 32, in the same manner as the signal processing portion 34 of the embodiment described above.

According to such a magnetic sensor system, the outside signal processing portion (for example, a microprocessor) which is provided on the outside of the magnetic sensor 1 is used, thereby, it is possible to make the correction of the angle error of the output of the first Hall element 31 and the output of the second Hall element 32.

### 4. Other Embodiments of Magnetic Sensor System

In the embodiment described above, a case where the outside signal processing portion calculates the average of the output of the first Hall element 31 and the output of the second Hall element 32 is described, but the magnetic sensor system may be configured to include an outside storage portion that stores the difference between the output of the first Hall element 31 and the output of the second Hall element 32 per angle, and an outside signal processing portion that makes the correction by the addition or subtraction of the difference stored in the outside storage portion to or from the output of the first Hall element 31 or the output of the second Hall element 32.

According to such a configuration, the difference between the output of the X-direction Hall element 11 of the first Hall element 31 and the output of the X-direction Hall element 11 of the second Hall element 32 per angle, and the difference between the output of the Y-direction Hall element 12 of the first Hall element 31 and the output of the Y-direction Hall element 12 of the second Hall element 32 per angle are stored in the outside storage portion, and the outside signal processing portion may make the correction of the angle error of the output of the first Hall element 31 and the output of the second Hall element 32 by adding or subtracting the difference between the output of the first Hall element 31 and the output of the second Hall element 32 with respect to one thereof. According to the configuration, since the outside signal processing portion does not perform the division, with respect to a case where the correction is made by “the calculation of the average of the output of the first Hall element 31 and the output of the second Hall element 32” according to the embodiment described above, it is possible to reduce the calculation load.

This disclosure may be used in the magnetic sensor which measures the magnetic flux density by using the Hall element, and the magnetic sensor system.

A feature of a magnetic sensor according to an aspect of this disclosure resides in that the magnetic sensor includes a first Hall element that measures magnetic flux density, a second Hall element that measures the magnetic flux density, and a base member where the first Hall element is mounted on one surface, and the second Hall element is mounted on the other surface, in which the first Hall element and the second Hall element are disposed such that a measurement surface of the first Hall element and a measurement surface of the second Hall element are parallel to each other, and are symmetrical to the base member.

According to such a configuration, in a case where a load is applied to the magnetic sensor, it is possible to configure phases of stress acting upon the first Hall element and stress acting upon the second Hall element so as to be reversed to each other. Therefore, it is possible to easily perform a correction of an angle error due to a phase error.

It is preferable that the first Hall element and the second Hall element are connected to each other in parallel, and the magnetic sensor further includes a signal processing portion that calculates an average of an output of the first Hall element and an output of the second Hall element.

According to this configuration, by calculating the average of two outputs of the first Hall element and the second Hall element, it is possible to easily cancel an influence of the load which is applied to the magnetic sensor.

Alternatively, the magnetic sensor may be configured such that the first Hall element and the second Hall element are connected to each other in parallel, and the magnetic sensor further includes a storage portion that stores a difference between an output of the first Hall element and an output of the second Hall element per angle, and a signal processing portion that makes a correction by addition or subtraction of the difference stored in the storage portion to or from the output of the first Hall element or the output of the second Hall element.

According to such a configuration, the difference between the output of the first Hall element and the output of the second Hall element per angle is stored in advance, and the calculation load of the signal processing portion is reduced, by the addition or subtraction of the stored difference. Thus, it is possible to make the correction of the angle error of the output of the first Hall element and the output of the second Hall element.

A feature of a magnetic sensor system according to another aspect of this disclosure resides in that the magnetic sensor system includes the magnetic sensor in which the first Hall element and the second Hall element are connected to each other in parallel, and an outside signal processing portion that calculates an average of an output of the first Hall element and an output of the second Hall element.

According to such a configuration, it is possible to make the correction of the angle error of the output of the first Hall element and the output of the second Hall element, by using the outside signal processing portion (for example, a microprocessor) which is provided on the outside of the magnetic sensor.

A feature of a magnetic sensor system according to still another aspect of this disclosure resides in that the magnetic sensor system includes the magnetic sensor, an outside storage portion that stores a difference between an output of the first Hall element and an output of the second Hall element per angle, and an outside signal processing portion that makes a correction by addition or subtraction of the difference stored in the outside storage portion to or from the output of the first Hall element or the output of the second Hall element.

According to such a configuration, the calculation load of the outside signal processing portion is reduced, by using the outside storage portion (for example, a nonvolatile memory), and the outside signal processing portion (for example, a microprocessor) which are provided on the outside of the magnetic sensor. Thus, it is possible to make the correction of the angle error of the output of the first Hall element and the output of the second Hall element.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A magnetic sensor comprising:
a first Hall element that measures magnetic flux density;
a second Hall element that measures the magnetic flux density; and
a base member where the first Hall element is mounted on one surface, and the second Hall element is mounted on the other surface,
wherein the first Hall element and the second Hall element are disposed such that a measurement surface of the first Hall element and a measurement surface of the second Hall element are parallel to each other, and are symmetrical to the base member.

2. The magnetic sensor according to claim 1,
wherein the first Hall element and the second Hall element are connected to each other in parallel, and
wherein the magnetic sensor further comprises a signal processing portion that calculates an average of an output of the first Hall element and an output of the second Hall element.

3. The magnetic sensor according to claim 1,
wherein the first Hall element and the second Hall element are connected to each other in parallel, and
wherein the magnetic sensor further comprises a storage portion that stores a difference between an output of the first Hall element and an output of the second Hall element per angle; and
a signal processing portion that makes a correction by addition or subtraction of the difference stored in the storage portion to or from the output of the first Hall element or the output of the second Hall element.

4. A magnetic sensor system comprising:
the magnetic sensor according to claim 1 in which the first Hall element and the second Hall element are connected to each other in parallel; and
an outside signal processing portion that calculates an average of an output of the first Hall element and an output of the second Hall element.

5. A magnetic sensor system comprising:
the magnetic sensor according to claim 1;
an outside storage portion that stores a difference between an output of the first Hall element and an output of the second Hall element per angle; and
an outside signal processing portion that makes a correction by addition or subtraction of the difference stored in the outside storage portion to or from the output of the first Hall element or the output of the second Hall element.
